(19) United States
(12) Patent Application Publication
(10) Pub. No.: US 2005/0051273 A1
(43) Pub. Date: Mar. 10, 2005

(54) Plasma processing apparatus

(76) Inventors: Kenji Maeda, Tsuchiura-shi (JP); Kenetsu Yokogawa, Tsurugashima-shi (JP); Tsuyoshi Yoshida, Hikari-shi (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/654,010

(22) Filed: Sep. 4, 2003

(51) Int. Cl. C25B 9/00; H01L 21/306

(52) U.S. Cl. 156/345.48; 156/345.47; 156/345.43

(57) ABSTRACT

A plasma processing apparatus capable of processing a wafer having a diameter of 300 mm or greater with high accuracy and uniformity, the apparatus comprising a decompressable container 1, a stage 2 disposed within container 1 and supporting a wafer 3 thereon, a substantially circular conductive plate 7 disposed substantially in parallel with the wafer 3 and opposing the stage 2, and a high frequency power source 11 connected to the conductive plate 7 and supplying power to generate a plasma within a space interposed between the stage 2 and the conductive plate 7, characterized in that a frequency f1 of the power is within the range of 100 MHz<F1<(0.6×C)/(2.0×D) Hz with respect to a speed of light C in vacuum and a diameter D of the wafer being processed.

### FIELD OF THE INVENTION

The present invention relates to a plasma processing apparatus that utilizes a plasma generated within a decompressed chamber to carry out processes such as etching and ashing to a substrate such as a semiconductor wafer.

### DESCRIPTION OF THE RELATED ART

In the field of semiconductor device fabrication, plasma processing apparatuses are widely used for deposition and etching processes. Along with the shrinking of the device or the enlarging of the wafer diameter, there are increasing demands for higher performance of the plasma processing apparatus. Taking a plasma etching apparatus as an example, there are demands for higher processing performances such as vertical workability (anisotropic etching), higher selectivity and workability with respect to the mask material or substrate material, higher etching rate and uniform processing, and for techniques to maintain the processing performance for a long period of time.

There have been various approaches aimed at improving the process performance. Previously, an RIE (reactive ion etcher)-type plasma source as shown in FIG. 2 has been utilized for anisotropic etching. However, the RIE device has a drawback in that the plasma density and the ion energy incident on the wafer cannot be controlled independently, since the source power for generating the plasma and the bias power for drawing ions toward the wafer are common. Presently, therefore, a plasma-source plus wafer-bias type plasma processing apparatus comprising plural high frequency power sources is mainly used.

The plasma processing devices mainly used at present can be categorized as follows based on the difference in plasma sources; an ICP (inductively coupled plasma), a dual frequency CCP (capacitive coupled plasma), a microwave ECR (electron cyclotron resonance) and a UHF (ultra high frequency)—ECR. The dual frequency CCP and the UHF-ECR plasma sources are mainly used for etching insulating films such as low-k films, silicon oxide films and silicon nitride films. These etching apparatuses for etching insulating films all adopt a parallel plate structure. The frequency of the power for the plasma source ranges approximately between 13.56 MHz and 500 MHz, and the frequency of the bias power source is set to a lower frequency, approximately between 400 kHz and 13.56 MHz, so as to minimize the influence to the plasma source and to draw in ions efficiently.

According to such prior art etching apparatuses, the surface of an upper electrode is typically formed of silicon. CF-based gases are mainly used to etch silicon oxide films, but multiple dissociation of the CF-based gas is caused by plasma, which inevitably generates F radicals causing deterioration of the selectivity with respect to the resist or the substrate nitride film. The above structure aims at scavenging F radicals causing reaction of the F radicals contained in the gas with the silicon constituting the upper electrode.

On the other hand, an art related to the confinement of plasma aimed at maintaining a stable processing performance for a long period of time has become increasingly important. It is extremely unfavorable from the point of view of stability and contamination for the plasma to spread to regions other than directly above the processed wafer, that is, approximate the side walls or the bottom wall of the reaction chamber or under the electrode. The damaging of side walls or other parts of the reaction container by the plasma spreading to regions other than directly above the wafer causes heavy-metal contamination of the wafer or generation of particles, leading to significant deterioration of the yield factor. If a gas having a strong deposition property is used, deposition is formed to the side walls of the container, causing contaminants to be produced when the deposition on the side walls fall off.

There is a proposal to form a physical confinement of the plasma using a shield ring or a baffle plate as a countermeasure against the undesired diffusion of plasma (refer for example to patent document 1; Japanese Patent Laid-Open Publication No. 8-335568). Another proposal discloses a cylindrical confinement arrangement formed by superposing plural rings (refer for example to patent document 2; Japanese Patent Laid-Open Publication No. 9-27396). Yet another proposal teaches retaining the plasma using a magnetic field formed by permanent magnets (refer for example to patent document 3; Japanese Patent Laid-Open Publication No. 9-219397).

With respect to a low pressure process, there exists a proposal in which electromagnetic waves ranging between 300 MHz and 500 MHz are applied to an upper antenna, generating a magnetic field around 100 G to 200 G directly below the antenna by an external coil, and generating plasma by the interaction between the electromagnetic waves and the magnetic field (refer for example to patent document 4; Japanese Patent Laid-Open Publication No. 2000-150485). This arrangement utilizes an ECR effect caused by the interaction of electromagnetic waves and magnetic field, by which plasma is efficiently generated under a pressure as low as 0.2 Pa to 4 Pa. Moreover, since a frequency in the 300 MHz−500 MHz band is utilized, the electric temperature is maintained low, so the multiple dissociation of the CF-based gas can be suppressed. According to this arrangement, since plasma is generated efficiently under low pressure, uniform density of the plasma above the wafer can be realized using a source power smaller than that of the CCP with a frequency of 27 MHz as disclosed in patent documents 1 and 2.

According to the disclosure of patent document 1, an upper electrode is disposed on a surface opposite a lower electrode on which a wafer is mounted, and a high frequency of 27.12 MHz is applied to the upper electrode while a high frequency of 800 kHz is applied to the lower electrode. The apparatus further comprises a shield ring and a baffle plate for retaining the plasma generated mainly by the high frequency applied to the upper electrode to the area above the wafer.

However, it is difficult for such prior art apparatus to correspond to a next-generation processing in which the object is further shrinked. That is, processing under lower pressure is desirable to cope with microfabrication, but it is known that when 27.12 MHz frequency is applied as source power, it is difficult to generate plasma with a sufficient density to realize processing under a pressure as low as around 0.2 Pa to 4 Pa. Applying greater source power to increase the plasma density is not desirable, not only because it deteriorates efficiency, but also because it increases the density of unnecessary plasma diffusing from above the wafer.

Furthermore, the shield ring and the baffle plate that contribute to preventing the unnecessary diffusion of plasma and improving the efficiency of the source power in the prior art apparatus can not exert these effects sufficiently under a low pressure condition in which the diffusion velocity of plasma is high. Another drawback of the prior art apparatus is that when the shield ring and baffle plate are exposed directly to high density plasma and subjected to surface reaction, contaminants deteriorating the process performance may be generated within the processing chamber, by which the etching performance is varied with time. In order to prevent such problem, the above components must be replaced frequently, by which the running cost of the apparatus is increased.

Patent document 2 discloses an arrangement in which a pair of substantially flat circular electrodes is disposed in parallel within a processing chamber, the upper electrode having a high frequency of 27.12 MHz applied thereto and the lower electrode having a high frequency of 2 MHz applied thereto, further comprising a cylindrical confinement structure formed by superposing rings for retaining the plasma to the area above the wafer.

However, this prior art arrangement also suffered similar drawbacks as the apparatus of patent document 1 in carrying out processing under lower pressure. Another drawback of this arrangement is that when the plurality of confinement rings are disposed close to one another to exert sufficient plasma retaining effects, the exhaust conductance becomes too small, making it impossible for the arrangement to correspond to a process requiring a large gas flow. Furthermore, the same drawback as patent document 1 occurs by the interaction between the plasma and the rings.

According to the teachings of patent documents 1 and 2, it is necessary to increase the power supplied to the electrodes or to the antenna and the electrode in order to raise the plasma density in the area above the wafer, and both teachings have drawbacks related to the demand for retaining the otherwise diffusing plasma to a predetermined area.

Furthermore, patent document 3 discloses an art to retain plasma by forming a magnetic field locally within the plasma generating space of the processing chamber. According to this prior art, permanent magnets are disposed to the area below the stage for placing the wafer and the side walls of the processing chamber. Since plasma cannot be diffused easily in the direction traversing a magnetic field, the permanent magnets are disposed so as to generate lines of magnetic force in the direction perpendicular to the diffusion flux of the plasma.

However, this prior art arrangement has a drawback in that the local magnetic field formed by the magnets causes the generation of a local plasma, by which the surface of the walls near the magnets are wasted. This arrangement has yet another drawback in that the magnetic field generated by the magnets affects the processing on the wafer and causes charging damage.

Patent document 4 discloses an art using UHF-ECR, which is advantageous when applied to processes under lower pressure, but has some drawbacks compared to other methods for generating plasma for processing wafers having a large diameter. For instance, the half wavelength of a 450 MHz electromagnetic wave in vacuum is approximately 330 mm, so according to this apparatus, it is difficult to generate a plasma having uniform density for treating 300 mm wafers and subsequent-generation wafers in which the half wavelength of the electromagnetic wave is substantially equal to the wafer diameter. Therefore, according to this prior art apparatus, it is difficult to carry out processes that require high accuracy such as a stopperless dual damascene processes to the wafer, and it is also difficult to carry out accurate processing to wafers having a relatively large diameter under lower pressure.

### SUMMARY OF THE INVENTION

The object of the present invention is to provide a plasma processing apparatus capable of processing a wafer having a diameter of 300 mm or larger with high uniformity and high accuracy. Another object of the present invention is to provide a plasma processing apparatus capable of carrying out highly accurate processing stably for a long period of time by suppressing the diffusion of plasma within the processing chamber.

The object of the present invention is realized by a plasma processing apparatus comprising: a stage disposed within a decompressable container and supporting a wafer thereon; a substantially circular conductive plate disposed substantially parallel to the wafer and opposing the stage; and a power source connected to the conductive plate and supplying power to generate a plasma within a space interposed between the stage and the conductive plate; wherein a frequency f1 of the power being supplied is within the range of 100 MHz<f1<(0.6×C)/(2.0×D) Hz, in which C represents a speed of light in vacuum and D represents a diameter of the wafer being processed.

The object of the present invention is also realized by the above plasma processing apparatus, wherein apart from said power, a power having a frequency between 100 kHz and 20 MHz is supplied to the conductive plate. Even further, the object is achieved by the above plasma processing apparatus, wherein the diameter of the wafer is approximately 300 mm, and the frequency f1 of the power being supplied to the conductive plate is 100 MHz<f1<300 MHz. Moreover, the object is achieved by the above plasma processing apparatus, wherein the apparatus further comprises a magnetic field generator for generating a magnetic field to the space interposed between the stage and the conductive plate.

Furthermore, the object is achieved by a plasma processing apparatus comprising: a stage disposed within a decompressable container and supporting a wafer thereon; a substantially circular conductive plate disposed substantially parallel to the wafer and opposing the stage within the container; a power source connected to the conductive plate and supplying power to generate a plasma within a space interposed between the stage and the conductive plate; and an insulative member disposed at an outer circumference of the conductive plate and facing the space; wherein a frequency f1 of the power being supplied is 100 MHz<f1<(0.6×C)/(20.0×D) Hz, in which C represents a speed of light in vacuum and D represents a diameter of the wafer being processed.

The object is further achieved by the above plasma processing apparatus, wherein the insulative member disposed at the outer circumference of the conductive plate is formed of quartz or aluminum oxide.

### BRIEF DESCRIPTION OF THE DRAWINGS

FIG. 1 is a cross-sectional view showing a first embodiment of a plasma processing apparatus according to the present invention;

FIG. 2 is a view showing a frame format of a plasma processing apparatus according to the prior art;

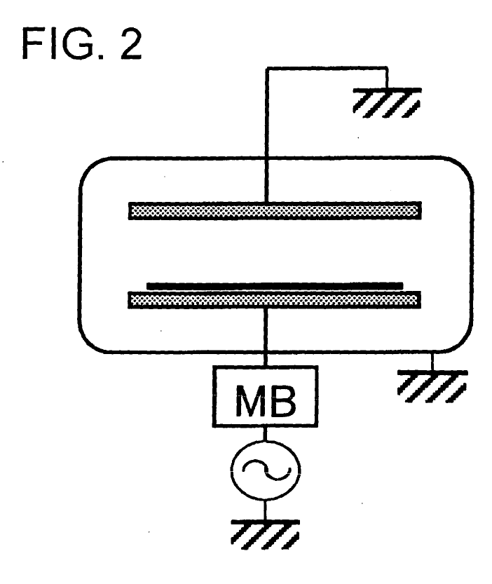

FIG. 3 is a cross-sectional view showing an experimental apparatus used for examining the source frequency;

FIG. 4 is a chart showing the etching rate distribution when the source frequency is varied;

FIG. 5 is a chart showing the source power dependency of the wafer bias voltage when the source frequency is varied;

FIG. 6 is a chart showing the source frequency dependency of the emission intensity from unnecessary plasma existing in areas other than directly above the wafer;

FIG. 7 is a chart showing the magnetic field intensity dependency of the etching rate distribution using the plasma processing apparatus according to the present invention;

FIG. 8 is a cross-sectional view showing the second embodiment of the plasma processing apparatus according to the present invention;

FIG. 9 is across-sectional view showing the third embodiment of the plasma processing apparatus according to the present invention; and

FIG. 10 is a cross-sectional view showing the fourth embodiment of the plasma processing apparatus according to the present invention.

### DETAILED DESCRIPTION OF THE PREFERRED EMBODIMENT

Now, the preferred embodiments of the present invention will be explained in detail with reference to the accompanying drawings.

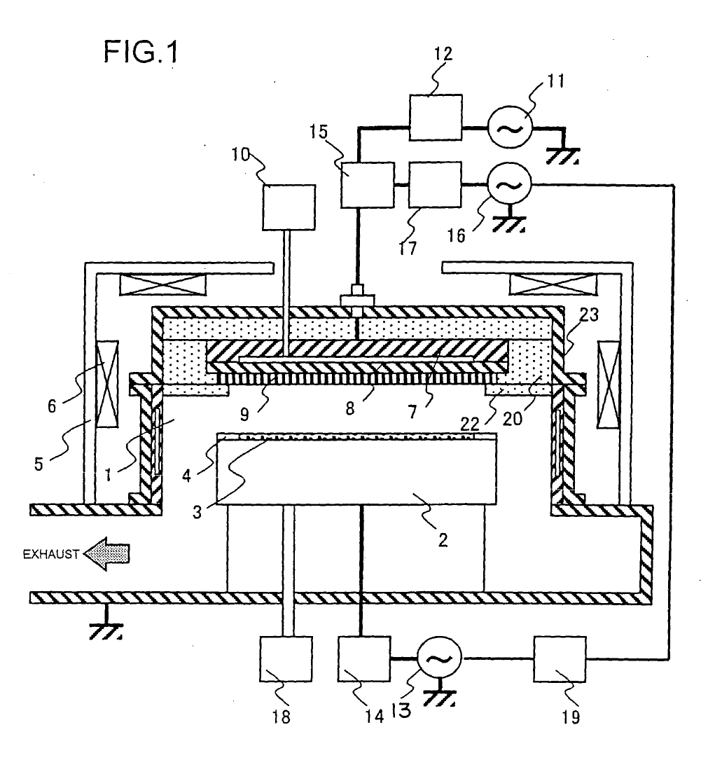

A first embodiment according to the present invention is illustrated in FIG. 1. FIG. 1 is a vertical cross-sectional view showing the outline of the structure surrounding a processing chamber (vacuum container) of a plasma processing apparatus according to the first embodiment of the present invention. The plasma processing apparatus according to the present invention comprises a vacuum processing chamber 1, a wafer mounting stage 2, a focus ring 4, a yoke 5, a coil 6, an antenna 7, a gas dispersion plate 8, a shower plate 9, a gas supply system 10, a first high frequency power source 11, a first impedance matching network 12, a second high frequency power source 13, a second impedance matching network 14, a filter circuit 15, a third high frequency power source 16, a third impedance matching network 17, a temperature control unit 18, a phase control unit 19, an insulation ring 20 disposed on the outer circumference of the antenna, a silicon plate support ring 22 and an antenna lid 23. Inside a vacuum processing chamber 1 in vacuum and comprising a gas supply means 10 is disposed a wafer mounting stage 2, the temperature of which being controlled by a temperature control unit 18. A plate-shaped antenna 7 formed of a substantially circular conductive member is disposed on a surface substantially parallel to and facing the stage 2, with a predetermined space formed between the stage 2 and the antenna 7. A high frequency power is applied to the antenna 7 from a first high frequency power source 11 via a first impedance matching network 12. The electromagnetic waves emitted from the antenna 7 interact with the magnetic field produced in the space interposed between the antenna 7 and the stage 2 by an external coil 6 and a yoke 5 disposed along the outer circumference of the vacuum processing chamber 1, and plasma is generated. Furthermore, by applying high frequency bias to a wafer 3 being subjected to processing through a second high frequency power source 13 and a second impedance matching network 14 connected to the stage 2, the charged particles generated in the plasma are drawn toward the surface of the wafer 3, and the highly excited particles in the plasma react with the surface of wafer 3 to carry out plasma processing.

According to the present embodiment, the frequency f1 of the first high frequency power source 11 is selected from frequencies that preferably satisfy the following relation; 100 MHz<f1<(0.6×C)/(20.0×D), and more preferably, satisfy the following relation; 150 MHz<f1<(0.5×C)/(20.0×D), wherein D represents the diameter of the wafer being treated, and C represents the speed of light in vacuum. By utilizing the frequency band satisfying the above relation, highly uniform plasma can be efficiently generated directly above the wafer, and the generation of unnecessary plasma to the area other than directly above the wafer can be suppressed. In the present embodiment, the size of the wafer subjected to processing is 300 mm, and the source frequency f1 is set to 200 MHz.

Furthermore, the frequency of the second high frequency power source 13 for applying high frequency bias to the wafer is selected preferably between 100 kHz and 20 MHz, and more preferably between 400 kHz and 13.56 MHz, so that ions can be drawn efficiently toward the wafer without affecting the plasma being generated by the first high frequency power. In the present embodiment, a frequency of 4 MHz is used.

Moreover, a drooping magnetic field is generated by applying a predetermined current to the two lines of external coils. The interaction of this magnetic field with the electromagnetic waves emitted from the antenna 7 into the processing chamber enables plasma to be generated more efficiently, that is, enables plasma having a medium density that is most preferable for processing to be generated using an output from a lower power source (lower source power). Further, by controlling the current flowing through the coils and adjusting the magnetic field intensity, the form of the distribution of plasma density can be controlled.

Since the magnetic field intensity for causing electron cyclotron resonance (ECR) with a frequency of 200 MHz is approximately 70 G, the average magnetic field intensity in the discharge space is controlled to be within around 20 G to 70 G. The line of magnetic force formed by the yoke 5 and the coil 6 functions to prevent the plasma generated directly above the wafer from diffusing outward. The magnetic field intensity used in the plasma processing apparatus according to the present embodiment is reduced compared to a microwave ECR apparatus or an UHF-ECR apparatus. Therefore, the margin of charging damage to the wafer 3 is greatly improved, resulting in stable processing of the wafer 3 and improving the yield ratio. If a frequency smaller than 200 MHz is utilized, the range of the magnetic field is shifted toward the weaker side.

Next, we will explain the background of how we came to determine the frequency range of the apparatus, which is the characteristic property of the present embodiment. The property of the plasma varies greatly according to the composition of the discharge and the frequency of the discharge. Since the composition of the discharge varies greatly according to the object being etched and the specifics of the process being required, the present inventors used a UHF-ECR plasma, which is advantageous in carrying out processing under lower pressure, to examine the preferable discharge frequency range.

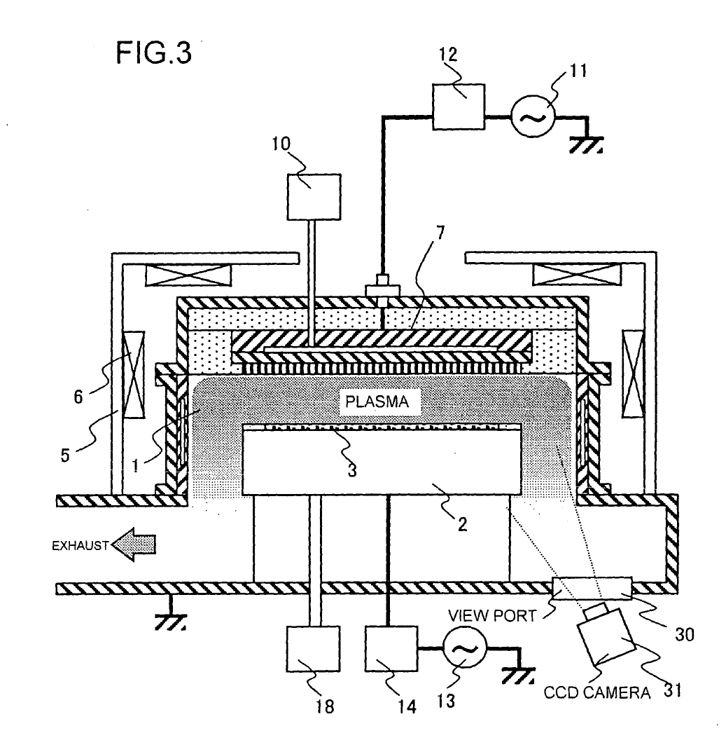

An experimental apparatus used for the examination is illustrated in FIG. 3. This experimental apparatus comprises a stage 2 for mounting a wafer disposed within a reaction chamber that can be decompressed and into which desired gas can be supplied. The apparatus further comprises a substantially circular antenna which is disposed substantially in parallel with and opposing the stage with a determined distance, the antenna 7 connected to a high frequency power source 11 that supplies power to the antenna 7 so as to generate plasma. By the interaction between the electromagnetic waves radiated from the antenna 7 by the supplied power and the magnetic field created by the external coils 6 disposed around the periphery of the reaction chamber 1, plasma is generated in the space formed between the stage 2 and the antenna 7. A wafer having a diameter of approximately 300 mm is transferred onto the stage via a conveyance system not shown, and high frequency bias is supplied to the wafer via a high frequency power source 13 connected to the stage, thereby actually etching the wafer. Further, a CCD camera 31 is positioned at a view port 30 disposed at a lower portion of the processing chamber so as to observe and record the emission of light by the unnecessary plasma spreading downward in the processing chamber. Upon examining the preferable frequency, four types of power sources, 450 MHz, 200 MHz, 68 MHz and 40 MHz, were used.

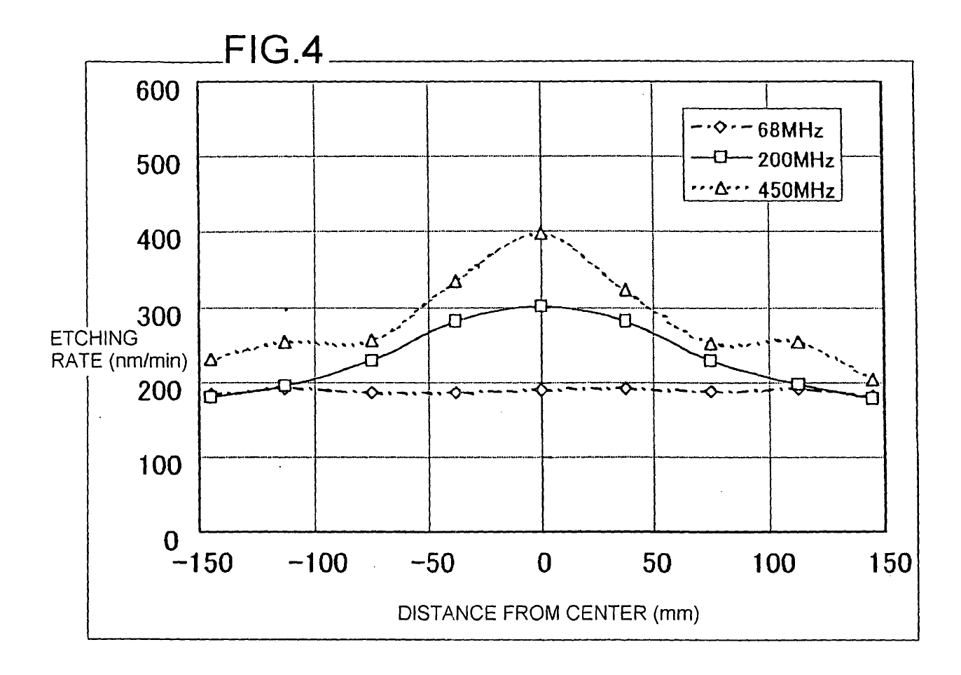

FIG. 4 shows a radial distribution of the etching rate of a silicon oxide film using a C₄F₈/Ar/O₂ based mixed gas for each frequency. The conditions of the experiment were common for all the frequencies, and the source power was set to 800 W, the bias power to 1000 W, the antenna-wafer distance to 30 mm and processing pressure to 2.0 Pa. No magnetic field was applied so as to examine only the pure influence of frequency. Since there is no interaction between the electric field and the magnetic field, the plasma was generated only by the high frequency electric field. Moreover, since the distance between the antenna and the wafer is set relatively short, the etching rate distribution is considered to directly reflect the distribution of the magnetic field intensity just below the antenna.

According to FIG. 4, the result of experiment using the frequency of 450 MHz shows that the minimal value of the etching rate existed around 150 mm and 200 mm in diameter, which indicates that the electric field intensity was weak at that portion. This is because the plasma excited by a frequency of around 450 MHz behaves like a surface wave plasma (SWP) instead of a capacitively-coupled plasma, even if the reactor takes on a parallel plate structure. In other words, the electromagnetic waves are transmitted through a sheath existing between the plasma and the antenna, and the standing wave pattern formed directly below the antenna determines the distribution of electric field intensity.

The plasma can also be considered as a dielectric substance, causing wavelength contraction of the electromagnetic waves transmitted through the sheath. According to the etching result using a frequency of 450 MHz, the distance between nodes is approximately 150 mm to 200 mm. By comparing this length with a half-wavelength of 330 mm in vacuum, the wavelength contraction rate K is calculated as being within the range of 0.45-0.6 (45% to 60%). This value will not vary greatly within the subject range of pressure, frequency and density.

According to the UHF-ECR plasma processing apparatus utilizing a frequency of 450 MHz, the actual processing is performed by applying a magnetic field. The application of magnetic field not only improves the efficiency of plasma generation but also enables control of the etching rate distribution. For example, if the etching rate without the application of a magnetic field is a simple center-high distribution, the coil current can be adjusted so that the interaction between the electromagnetic waves and the magnetic field becomes strong at the outer circumference of the antenna.

However, if the nodes of the standing waves appear within the wafer range subjected to processing as shown in the result of FIG. 4, it is difficult to control the etching rate by adjusting the magnetic field. In other words, a frequency according to which the nodes of the standing waves do not appear within the range of the wafer is the upper limit of the frequency for realizing a good plasma distribution controllability and uniform processing. That is, the half-wavelength κλ/2 of the standing wave formed below the antenna and the diameter D of the wafer should satisfy the relationship κλ/2>D. By substituting the value of the wavelength contraction rate κ=0.6 obtained by the result of experiment in the present inequality and solving the inequality for frequency f, the inequality can be described as f<(0.6×C)/(2×D), based on which the upper limit of the source frequency most preferable for solving the prior art problems is determined. In the inequality, C represents the speed of light in vacuum. According to this relation, f is smaller than 300 MHz when the wafer diameter is 300 mm, and it is clear from the result shown in FIG. 4 that according to the frequencies satisfying the present condition, no minimal value reflecting a node of the standing wave occurs in the etching rate distribution.

Based on the above discussion, it is clear that for the processing of a large-diameter wafer with a diameter over 300 mm, the source frequency should be lowered than 450 MHz to achieve advantageous distribution controllability and uniformity, but if the frequency is too low, the plasma generation efficiency is deteriorated and unnecessary plasma spreading out from directly above the wafer is increased. Therefore, we will now explain the background of how we have determined the lower limit of the preferable source frequency.

We have measured a peak-to-peak value (W-Vpp) of the voltage applied to the wafer with the bias power fixed to 1000 W, in order to examine how the plasma density directly above the wafer is varied in response to the frequency. Since the bias power is fixed, the W-Vpp value decreases when the plasma density above the wafer increases.

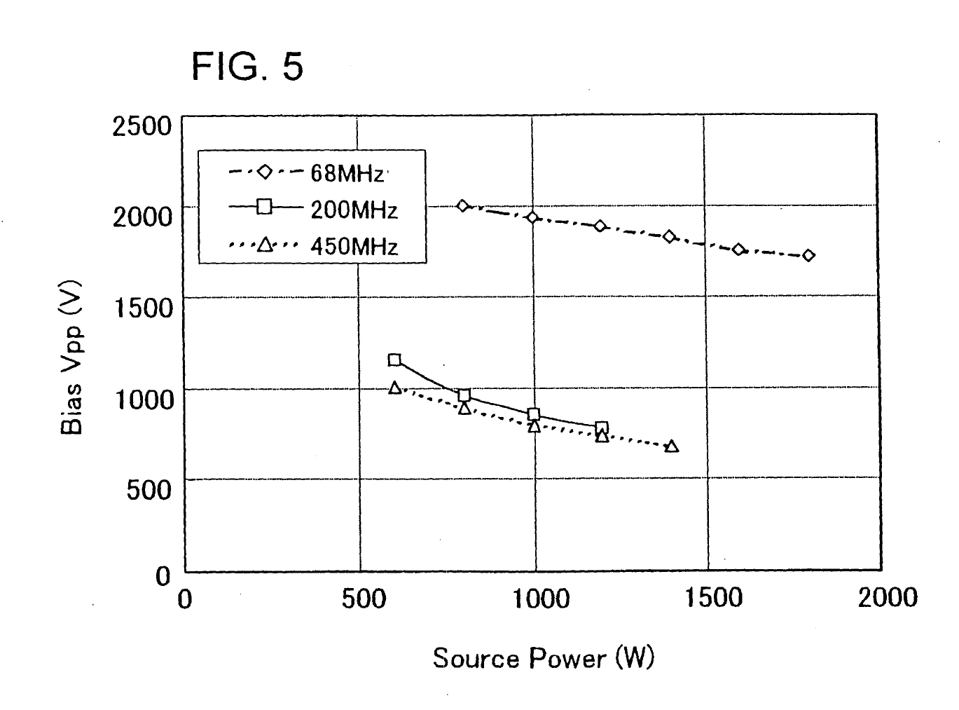

FIG. 5 shows an output dependency of the source high frequency power of W-Vpp according to each frequency. As shown in FIG. 5, though W-Vpp is not varied greatly between 450 MHz and 200 MHz, W-Vpp of 68 MHz is more than two times greater than that of 450 MHz. In other words, according to frequencies around 68 MHz, the plasma density above the wafer is significantly reduced compared to that of 450 MHz.

According to FIG. 5, the absolute value of gradient of W-Vpp with respect to the source power is around 0.4 for 450 MHz and 200 MHz, while 0.28 for 68 MHz. This means that with a frequency of 68 MHz, the plasma density directly above the wafer hardly increase seven when the source power is increased. It also means that the source power that does not contribute to increasing the plasma density above the wafer is consumed for the plasma spreading out from above the wafer.

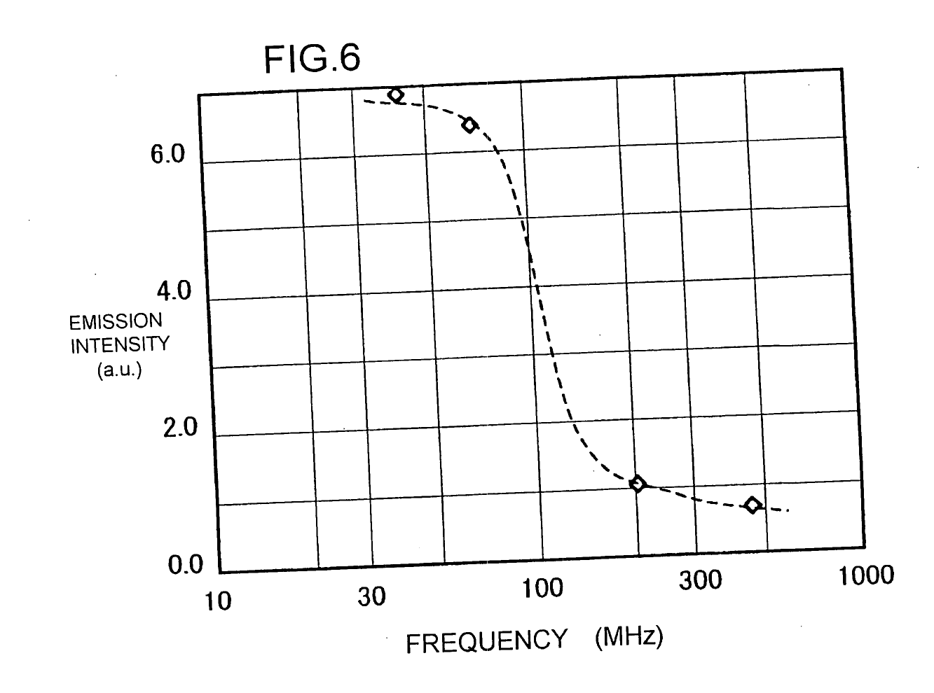

Next, FIG. 6 shows the frequency dependency of the emission intensity of plasma that has spread to the pipe-like outer periphery or to the lower area of the substantially cylindrical stage. The emission intensity was recorded using a manually controllable CCD camera and VTR, and digitized by image processing. The experiment conditions are common, according to which pressure is set to 2.0 Pa, the source power to 1200 W and bias power to 1000 W. It is recognized based on FIG. 6 that when the frequency is lowered from 450 MHz to 200 MHz, the emission intensity from the plasma spreading to the outer periphery or below the stage is somewhat increased. Further, the emission intensity is increased drastically when the frequency is approximately 100 MHz or smaller. This is considered to be caused by the plasma generation mechanism being changed according to frequencies. That is, at frequencies such as 450 MHz and 200 MHz, the plasma is generated and maintained in the manner of a surface wave plasma, and on the other hand, at frequencies such as 68 MHz and 40 MHz, the plasma behaves like a capacitively-coupled plasma.

According to the surface wave plasma, the plasma is generated and maintained by an electric field caused by electromagnetic waves transmitted through the sheath under the antenna, while according to the capacitively-coupled plasma, the plasma is maintained by a stochastic heating caused by the vibration of the sheath between electrodes. Further, compared to frequencies such as 450 MHz and 200 MHz, frequencies like 68 MHz and 40 MHz cause the plasma potential to fluctuate greatly with time, and plasma is considered to be generated also by the sheath generated between the inner walls of the processing chamber and the plasma spreading outward or downward of the stage. Therefore, the supplied source power is not utilized effectively to increase the density of plasma directly above the wafer, as shown by the source power dependency of W-Vpp of FIG. 5.

Currently, the inventors are not aware of a theory to determine at what frequency level does a surface wave plasma transit to a capacitively-coupled plasma, when the frequency is gradually reduced from a few hundred MHz. However, based on experimental results, we consider the boundary to be at or around 100 MHz. This is clear from the above description on the experimental results with reference to FIGS. 4 through 6.

As explained above, the lower limit of the source frequency for solving the problems of the prior art is 100 MHz, so by satisfying f>100 MHz, it becomes possible to utilize effectively the power being supplied and to suppress plasma spreading out from above the wafer, and moreover, becomes possible to suppress the generation of contaminants caused by deposition or chipping of the inner walls of the reactor, and to carry out stable processing for a long time.

According to the above example, we have discussed the preferable frequency range of the high frequency power source based on the structure of a UHF-ECR plasma processing apparatus, but the data used for the discussion was taken under a condition in which no magnetic field was generated, so the effectiveness of the present embodiment is not influenced by whether a magnetic field exists or not. Moreover, the plasma processing according to the present embodiment can be applied not only to an etching apparatus but to other plasma processing apparatuses as well.

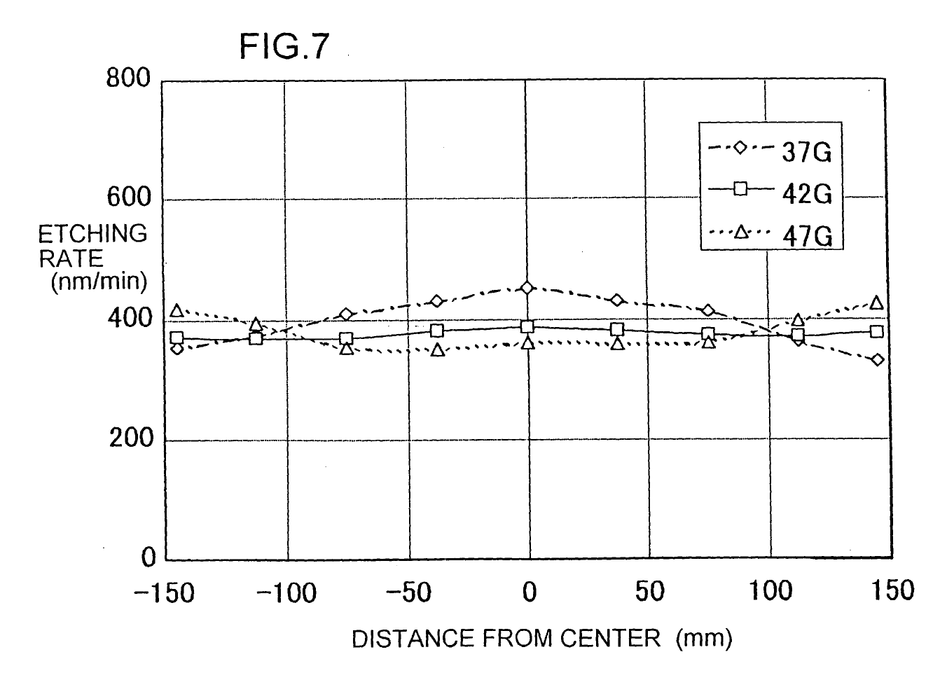

FIG. 7 shows one example of the etching result performed to a flat sample of a silicon oxide film by a C₄F₈/Ar/O₂ based mixed gas according to the plasma processing apparatus of the present embodiment. The effectiveness of the present embodiment can be recognized by the fact that the etching rate distribution is controlled to 15% for the convex form, 5% for flat and 10% for the concave form, by varying the average magnetic field intensity. Moreover, by varying the ratio of currents supplied to the two lines of coils and adjusting not only the average magnetic field intensity but also the shape of the line of magnetic force, it becomes possible not only to realize a super-uniform rate distribution but also to correspond widely to a variety of processes for treating low-k films or silicon nitride films.

Furthermore, the plasma generated by electromagnetic waves within the above frequency band has lower electron temperature compared to microwave ECR plasma or inductively-coupled plasma, so it prevents excessive dissociation of the process gas. The plasma having high electron temperature causes multiple dissociation of a CF-based gas, which is mainly used for etching insulating films such as silicon oxide films, and generates a large amount of F radicals that reduce the selective ratio between the resist as mask material or silicon nitride film as substrate. On the other hand, according to the plasma source of the present embodiment, the electron temperature is low, and plasma with medium density can be generated by adjusting the source power appropriately, so a preferable dissociation state enabling high selectivity processing can be realized.

Moreover, since the present embodiment enables stable plasma to be generated in a lower pressure compared to the capacitively-coupled plasma source using 27 MHz or 60 MHz bands, the present invention can be applied to vertical processing corresponding to further scale-down of the device.

According to the present embodiment, the stage for mounting the wafer is capable of an up-down movement so as to adjust the distance between the wafer to be processed and the lower surface of the antenna. As mentioned earlier, the selectivity is deteriorated by the multiple dissociation or excessive dissociation of the CF-based gas, but multiple dissociation can be suppressed by maintaining a suitable distance between the antenna surface and wafer. This is because the degree of dissociation of the process gas is influenced not only by electron temperature and electron density but by the residence time of gas. By cutting down the residence time of gas, that is, by reducing the distance between the antenna surface and wafer and to thereby reduce the volume of the plasma region, multiple dissociation is suppressed, and highly selective processing is realized.

Moreover, by reducing the distance between the antenna surface and wafer, the ratio of the surface coming into contact with plasma is increased.

The dissociation species that contribute most in etching a silicon oxide film is CF₂, but CF₂ is known to be generated not only by reaction within gas but also by transformation of dissociation species at surfaces. In other words, CₓF_{y}, which is a low level dissociation species of CF-based gas, adheres to the surface of the wafer or antenna, and the ions from the plasma become incident on the CₓF_{y}, causing generation of CF₂. Thus, CF₂ can be increased by increasing the ratio of the surface contacting the plasma, which improves the etching rate of the silicon oxide film, and improves the selective ratio with resist or the like.

However, if the distance between the antenna surface and the wafer is too small, other problems such as deterioration of process uniformity occurs. In the present embodiment, the distance between the wafer and antenna surface is within the range of 20 mm to 100 mm. Though the present embodiment utilizes an electrode capable of being moved up and down, this up-down movement mechanism can be omitted. In such case, the control range of the process is somewhat narrowed, but the cost of the system can be cut down.

Moreover, by contriving the material for the antenna surface coming into contact with plasma, the selectivity of the process can be improved further. According to the present embodiment, a roughly circular silicon plate is used as the material for the antenna surface. The silicon plate 9 has hundreds of fine holes with diameters ranging between around 0.3 mm and 0.8 mm. Moreover, a gas dispersion plate 8 having hundreds of fine holes with diameters ranging between 0.3 mm and 1.5 mm is disposed between the silicon plate 9 and antenna body 7. The space between the gas dispersion plate 8 and antenna 7 functions as a buffer chamber for the process gas, and the process gas supplied thereto from a gas supply system 10 is introduced uniformly into the processing chamber via the dispersion plate 8 and silicon plate 9. Further, in order to etch silicon oxide films and the like according to the present embodiment, process gas formed by mixing one, two or more CF-based gases such as C₄F₈, C₅F₈, C₄F₆ and C₃F₆, noble gas represented by Ar, and O₂, is utilized. In order to carry out a process requiring a higher selectivity, CO gas is added to the above gas.

One of the advantages of using silicon as antenna surface is that F radicals existing in the gas that deteriorate the selectivity when etching silicon oxide films can be scavenged by the reaction with silicon. According further to the present embodiment, a third high frequency power source 16 is connected to the antenna 7 via a filter unit 15 and a third impedance matching network 17. Antenna bias is applied to the antenna from the third high frequency power source 16 to thereby control the reaction for scavenging F radicals at the antenna surface independently from controlling the plasma density. According to this embodiment, fine patterns and profiles can be controlled easily.

Though silicon is used as antenna surface material in the present embodiment, other materials such as silicon carbide, glassy carbon, quartz, anodized aluminum and polyimide can be used, corresponding to the object to be etched. The diameter Da of the antenna surface that directly contacts the plasma should fall within the range of 0.8D<Da<1.2D with respect to wafer diameter D from the point of view of uniform surface reaction.

The frequency of the third high frequency power source 16 for providing antenna bias is determined preferably between 100 kHz and 20 MHz, and more preferably between 400 kHz and 13.56 MHz, so as not to affect the plasma generated by the first high frequency power. The filter unit 15 prevents the first high frequency power from reaching the third high frequency power source and the third high frequency power from reaching the first high frequency power source.

A roughly ring-shaped focus ring 4 is disposed so as to surround the wafer 3 on the outer circumference of the stage 2, in order to control the density distribution of the active species within the gas. In the present embodiment, the focus ring 4 is made of silicon. The average density of the F radicals within the gas can be controlled by applying antenna bias or by varying the distance between the antenna surface and wafer, and the density distribution of the F radicals on the wafer surface can be controlled in detail by further disposing a focus ring 4.

The F radicals caused by the multiple dissociation of process gas can also be consumed by the resist on the wafer surface. If there is no member disposed in the region outside the wafer that consumes F radicals, the F radical density will become high at the outer periphery of the wafer in comparison with the center of the wafer, but the focus ring 4 functions to suppress this phenomenon. By branching the wafer bias power and applying the same to the focus ring 4, the effect of suppressing F radical density at the outer periphery portion can be improved.

Though silicon is used as focus ring material in the present embodiment, other materials such as silicon carbide, glassy carbon, quartz, anodized aluminum and polyimide can be used, corresponding to the object to be etched. Moreover, though not illustrated, the process gas discharge can be divided into two lines, thereby controlling the distribution of active species within the gas.

One object for using a frequency of 200 MHz for the first high frequency power source in the present embodiment is to suppress the unnecessary plasma in areas other than directly above the wafer, but the effect of suppressing unnecessary plasma can be further improved by utilizing a completely equal frequency for both the antenna bias and the wafer bias, and providing a phase difference of substantially 180 degrees between the antenna bias and wafer bias using a phase control unit 19.

The plasma potential of the plasma generated by the first high frequency power is affected by the wafer bias and the antenna bias, and fluctuates with time. By varying the phase of the wafer bias and antenna bias by 180 degrees, the time-average of the plasma potential can be suppressed to a low value, and thus unnecessary plasma can be suppressed. The energy of ions being incident on the inner walls of the processing chamber and side walls of the stage from the unnecessary plasma can thereby be reduced, and damage to the walls can be cut down. This leads to the suppression of contaminants caused by wall damage, and contributes to improving the yield factor and operating ratio of the apparatus. Further, the side walls of the processing chamber and the antenna body 7 are controlled to a fixed temperature by a temperature control unit not shown, so that the apparatus is capable of maintaining a stable processing performance for a long time.

The plasma processing apparatus according to the present embodiment having the above-explained structure is capable of processing a large area, such as a wafer having a diameter of over 300 mm, under a low-pressure condition suitable for carrying out microfabrication, the process being highly uniform and with a high selective ratio, and requiring low consumption power to carry out high speed processing. The unnecessary plasma existing in areas other than directly above the wafer is suppressed, by which the contaminants causing deterioration of the yield factor is reduced, and stable and precise processing can be carried out for a long period of time. The suppression of unnecessary plasma further contributes to cutting down the running cost of the apparatus.

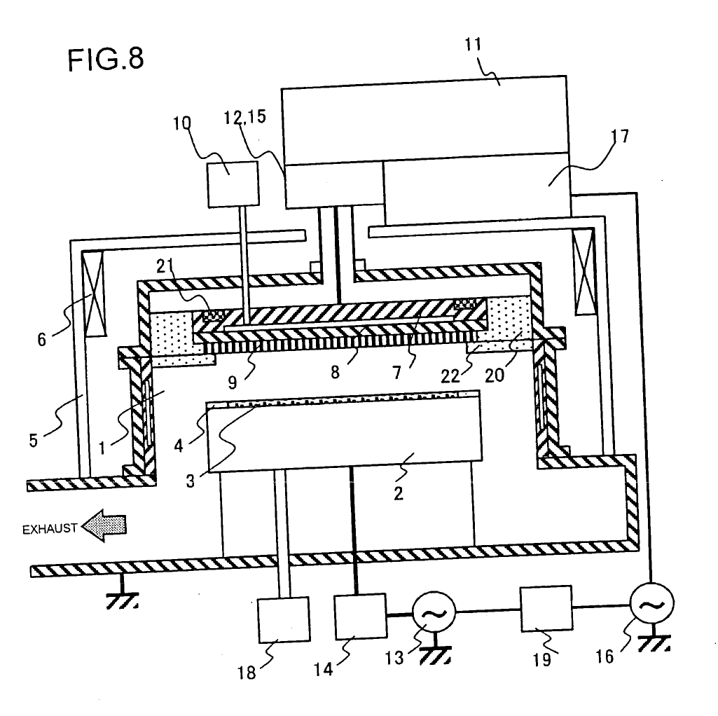

Next, the second embodiment of the present invention will be explained with reference to FIG. 8. According to the second embodiment, in addition to the advantages of the first embodiment, the system structure is more aware of footprint and cost. The basic structure is similar to embodiment 1, so detailed explanations on the common components are omitted.

The second embodiment of the invention comprises, in addition to the yoke 5 and coil 6 being the first means for generating a magnetic field in the discharge space, a substantially ring-shaped second magnetic field forming means 21 disposed above the antenna. The second magnetic field forming means 21 is a permanent magnet made of materials such as ferrite, samarium-cobalt or neodymium-ferrum-boron, the use of which allows a more detailed magnetic field control inside the discharge space at low cost.

In the first embodiment, the magnetic field forming means comprises only a yoke 5 and a coil 6, and in order to carry out fine magnetic field control, two lines of coils to which are supplied different currents from separate DC power sources are disposed so as to control the magnetic field intensity and the shape of the lines of magnetic force. If there is only one line of coil 6, only the magnetic field intensity can be controlled and thus the control range is narrowed. On the other hand, if the number of coils and the number of DC power sources connected thereto are increased, the manufacturing cost and running cost of the apparatus are increased, and thus the cost of the semiconductor device manufactured using the plasma processing apparatus is increased.

According to the second embodiment introducing the second magnetic field generator 21, both the magnetic field intensity and the shape of the line of magnetic force can be varied simultaneously using only one coil and one DC power source. This is because the magnetic field in the discharge space is formed by the magnetic field generated by the second magnetic field generator 21 having a fixed magnetic field intensity and fixed line of magnetic force being superposed on the magnetic field formed by the first magnetic field generator 6 having a magnetic field intensity that can be varied by current.

The shape of the permanent magnet utilized as the second magnetic field generator 21 can be substantially ring-shaped, but considering cost, it may be more preferable to substitute the same with a ring-like magnet divided into plural portions and disposed in a ring-like manner or with a number of rectangular or cylindrical permanent magnets disposed substantially in a ring.

Further, according to the prior art UHF-ECR apparatus, a large-sized triple stub tuner was used in the first impedance matching network 12 for matching the high frequency power source 11 as plasma source (with a frequency of 450 MHz, for example) and the plasma load. On the other hand, according to the present embodiment, a smaller impedance matching network can be used because a lower frequency of around 200 MHz is used as the power source. Thus, a cavity-type impedance matching network or a vacuum condenser-type impedance matching network can be used, for example. Moreover, since the power source body can be miniaturized, it is possible to dispose the power source above the processing chamber, or actually, above the yoke 5.

According to the second embodiment illustrated in FIG. 8, a power source (first high frequency power source) 11, an antenna-biasing impedance matching network (third impedance matching network) 17, and units 12 and 15 combining source impedance matching network and filter are disposed above the yoke 5. This arrangement allows the footprint of the overall apparatus including the power source unit to be reduced. Furthermore, the distance between the power source and plasma load is minimized, so the loss of the high frequency power via the transmission line can be cut down to a minimum.

Further according to the second embodiment, the antenna body 7 and the antenna circumference insulation ring 20 constitute a vacuum seal structure. In comparison to the first embodiment in which the whole antenna body is introduced in vacuum and the antenna lid 23 used as vacuum seal, the second embodiment is advantageous in that the structure is simplified and the number of components of the system is cut down, leading to cost reduction. In comparison to the first embodiment in which the electromagnetic wave path between the first impedance matching network and the plasma load is almost completely in vacuum, the second embodiment is advantageous in that the unit for supplying refrigerant or gas to the antenna is disposed in the atmosphere, reducing the risk of abnormal discharge and improving reliability of the apparatus.

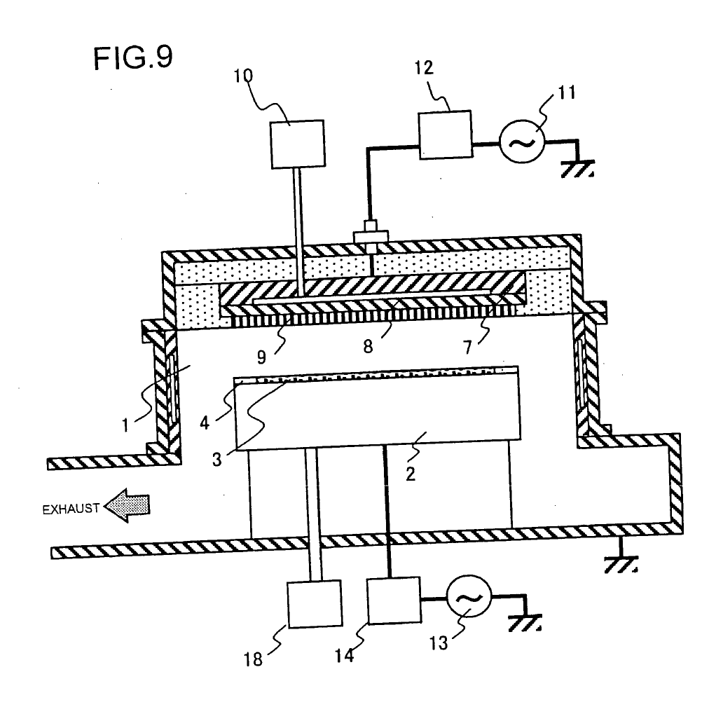

Next, the third embodiment of the present invention will be explained with reference to FIG. 9. The basic structure of the present embodiment is similar to that of embodiment 1, so only the portions different from embodiment 1 are explained. The plasma processing apparatus according to embodiment 3 comprises a first high frequency power source 11 and a second high frequency power source 13.

First, in comparison with the first embodiment, the present embodiment eliminates the means for forming a magnetic field in the discharge space, that is, eliminates the yoke 5 and coil 6 of FIG. 1 and the DC power source not shown. According to this arrangement, the manufacture cost and running cost of the apparatus are reduced significantly. On the other hand, the frequency of the first high frequency power source 11 according to the third embodiment should preferably be set to a lower frequency than the first embodiment, for example, between 100 MHz and 180 MHz, since the flexibility for controlling the density of the plasma using the magnetic field is deteriorated.

The third embodiment does not comprise a third high frequency power source for actually controlling the active species in the gas or a third impedance matching network. Though the controllability of the active species in the gas is somewhat deteriorated, the manufacturing and running costs of the apparatus are cut down. Moreover, though not shown in FIG. 9, it is possible to provide two series of process gas supplying to the apparatus so as to control the density and distribution of active species within the gas.

As explained above, the third embodiment of the present invention provides a plasma processing apparatus that can be manufactured and operated at lower cost.

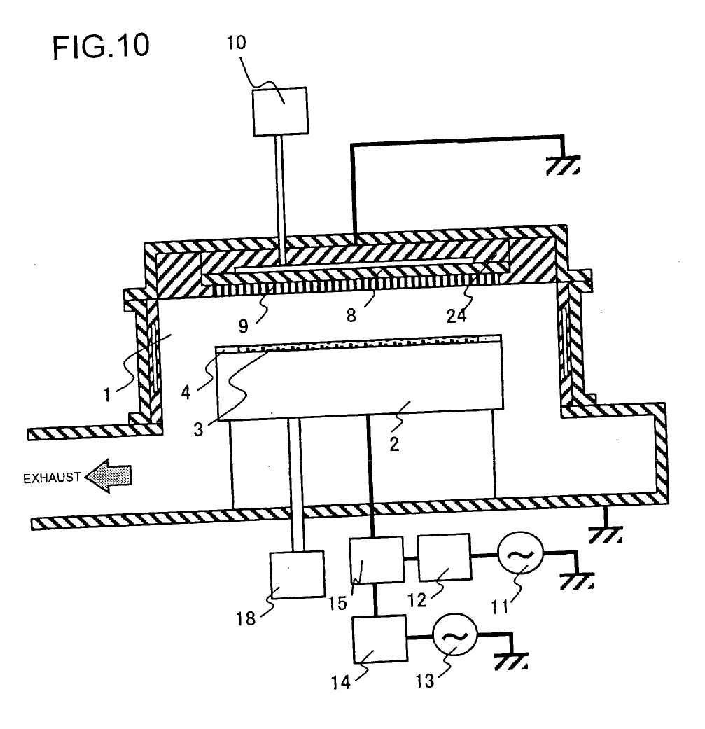

Next, the fourth embodiment of the present invention will be explained with reference to FIG. 10. Explanations of the portions of the apparatus that overlap with the previous embodiments are omitted.

According to the fourth embodiment, a first high frequency power source 11 is connected via filter unit 15 and an impedance matching network 12 to a stage 2 for supporting a wafer, so that the wafer stage itself also functions as the antenna for generating plasma. The yoke 5 and coil 6 for forming a magnetic field within the discharge space, the third high frequency power source 16 and the third impedance matching network 17, all of which are illustrated in FIG. 1, are omitted in the arrangement of the fourth embodiment. The frequency of the first high frequency power source of embodiment 4 should preferably be somewhat lower than that of embodiment 1, that is, approximately within the range of 100 MHz to 180 MHz, since controllability by the magnetic field cannot be expected.

The characteristic property of the present embodiment is to enable the apparatus to omit the upper antenna 7 by forming a wafer stage to also function as the antenna. According to the present arrangement, the surface facing the wafer is disposed not with an antenna but with an earthed gas supply system. Thereby, the structure of the surface opposing the wafer is simplified significantly, contributing to cutting down the costs further. The earthed gas supply system comprises an earth electrode 24, a gas dispersion panel 8 and a silicon plate 9. Further, the earth electrode 24 and gas dispersion panel 8 can be formed integrally with the lid portion of the processing chamber. Though the present embodiment has a drawback in that the process window is narrowed, by fine-tuning the plasma processing apparatus to correspond to a specific process, the apparatus can be provided at low cost.

As explained above, the present embodiment provides a plasma processing apparatus for treating using plasma a semiconductor substrate disposed inside a processing chamber (vacuum container), wherein the process is advantageously achieved to a wide area in a uniform manner for a wafer having a diameter of 300 mm or greater under low pressure suitable for microfabrication. Further, the present apparatus enables processing with high selectivity or high speed to be carried out with a low power consumption. Moreover, the present invention suppresses the dispersion of plasma to thereby prevent the generation of contaminants within the processing chamber, realizing a stable, high-quality processing for a long time.

1. A plasma processing apparatus comprising:
a stage disposed within a decompressable container and supporting a wafer;
a substantially circular conductive plate disposed substantially parallel to the wafer and opposing the stage; and
a power source connected to the conductive plate and supplying power to generate a plasma within a space interposed between the stage and the conductive plate; wherein
a frequency f1 of the power being supplied is 100 MHz<f1<(0.6×C)/(20.0×D) Hz, in which C represents a speed of light in vacuum and D represents a diameter of the wafer being processed.

2. The plasma processing apparatus according to claim 1, wherein apart from said power, a power having a frequency between 100 kHz and 20 MHz is supplied to the conductive plate.

3. The plasma processing apparatus according to claim 1 or claim 2, wherein the diameter of the wafer is approximately 300 mm, and the frequency f1 of the power being supplied to the conductive plate is 100 MHz<f1<300 MHz.

4. The plasma processing apparatus according to claim 1, claim 2 or claim 3, wherein the apparatus further comprises a magnetic field generator for generating a magnetic field in the space interposed between the stage and the conductive plate.

5. A plasma processing apparatus comprising:
a stage disposed within a decompressable container and supporting a wafer;
a substantially circular conductive plate disposed substantially parallel to the wafer and opposing the stage within the container;
a power source connected to the conductive plate and supplying power to generate a plasma within a space interposed between the stage and the conductive plate; and
an insulative member disposed at an outer circumference of the conductive plate and facing the space; wherein
a frequency f1 of the power being supplied is 100 MHz<f1<(0.6×C)/(2.0×D) Hz, in which C represents a speed of light in vacuum and D represents a diameter of the wafer being processed.

6. The plasma processing apparatus according to claim 5, wherein the insulative member disposed at the outer circumference of the conductive plate is formed of quartz or aluminum oxide.
